(19) United States
(12) Patent Application Publication
(10) Pub. No.: US 2025/0366034 A1
(43) Pub. Date: Nov. 27, 2025

(54) FIELD-EFFECT TRANSISTOR AND PREPARATION METHOD THEREFOR, AND MEMORY AND DISPLAY

(71) Applicant: INSTITUTE OF MICROELECTRONICS OF THE CHINESE ACADEMY OF SCIENCES, Beijing (CN)

(72) Inventors: Ming LIU, Beijing (CN); Ling LI, Beijing (CN); Di GENG, Beijing (CN); Xinlv DUAN, Beijing (CN); Congyan LU, Beijing (CN)

(73) Assignee: INSTITUTE OF MICROELECTRONICS OF THE CHINESE ACADEMY OF SCIENCES, Beijing (CN)

(21) Appl. No.: 18/873,673

(22) PCT Filed: Aug. 31, 2022
(86) PCT No.: PCT/CN2022/116073

§ 371 Date: Dec. 10, 2024

(30) Foreign Application Priority Data
Jun. 10, 2022 (CN) 202210657793.9

(51) Int. Cl. H10D 30/67; H10D 30/01; H10D 86/40

(52) U.S. Cl. CPC H10D 30/6728; H10D 30/0318; H10D 30/6755; H10D 30/6757; H10D 30/6738; H10D 30/6739; H10D 86/423

(57) ABSTRACT

Disclosed herein are a field effect transistor and a preparation method therefor, and a memory and a display. The field effect transistor comprises: a first source/drain layer (1), an insulating layer (2) and a second source/drain layer (3), which are sequentially stacked; and a gate electrode (5) and a channel layer (4), which surrounds the gate electrode (5), wherein the gate electrode (5) and the channel layer (4) are located in the second source/drain layer (3) and the insulating layer (2), and the channel layer (4) is in contact with the first source/drain layer (1) and the second source/drain layer (3). The channel layer (4) comprises an outer layer and an inner layer (42), wherein the inner layer (42) is close to the gate electrode (5); the outer layer is in contact with the insulating layer (2), the first source/drain layer (1) and the second source/drain layer (3); and both the outer layer and the inner layer (42) are made of indium oxide. Since both the outer layer and the inner layer (42) of the channel layer (4) in the field effect transistor are made of indium oxide, the problems of further reducing the size of the transistor, reducing the power consumption and improving the contact performance can be solved.

### CROSS-REFERENCE TO RELATED PATENT APPLICATIONS

This application claims a priority from the Chinese Patent Application No. 202210657793.9, filed with the Chinese Patent Office on Jun. 10, 2022, entitled “FIELD-EFFECT TRANSISTOR AND PREPARATION METHOD THEREFOR, AND MEMORY AND DISPLAY”, content of which is incorporated herein by reference in its entirety.

### FIELD OF THE INVENTION

The present disclosure relates to a field effect transistor and a preparation method therefor, a memory, and a display.

### BACKGROUND OF THE INVENTION

According to Moore's Law, integrated circuits continue to develop towards finer dimensions, and advanced fabrication process is one of the most cutting-edge nodes of integrated circuit fabrication. Currently, the advanced fabrication process has evolved to nodes of 5/7 nm, which places extremely high demands on further miniaturization of transistor.

The design of a Fin Field Effect Transistor (FinFET), which is one key architecture for the current transistor, can greatly improve circuit control and reduce leakage current, while greatly shortening the gate length of the transistor. However, the architecture of the FinFET is suitable for 10-22 nm process. For processes below 10 nm, such as 7 nm, 5 nm, and 3 nm, it will be limited by the scaling of FinFET width and cannot guarantee high performance and low power consumption while continuing to shrink in size. On the other hand, the FinFET further suffers from poor contact performance.

Therefore, it becomes an urgent problem to be solved how to further reduce the size of the transistor, reduce the power consumption of the transistor, and improve the contact performance.

### SUMMARY OF THE INVENTION

According to the present disclosure, there is provided a field effect transistor and a method for preparing the same, a memory, and a display, solving the present technical problem of how to further reduce the size of the transistor, reduce power consumption, and improve contact performance.

According to a first aspect of the present disclosure, there is provided a field effect transistor including:

a first source/drain layer, an insulating layer, and a second source/drain layer stacked in sequence; and a gate and a channel layer surrounding the gate, which are located in the second source/drain layer and the insulating layer, in which the channel layer is in contact with the first source/drain layer and the second source/drain layer, where the channel layer includes an outer layer and an inner layer, the inner layer is close to the gate, the outer layer is in contact with the insulating layer, the first source/drain layer and the second source/drain layer, and both the outer layer and the inner layer are made of indium oxide.

According to a second aspect of the present disclosure, there is provided a method for preparing a field effect transistor including:
providing a substrate; forming a first source/drain layer, an insulating layer, and a second source/drain layer in sequence on the substrate; forming a hole extending to the first source/drain layer within the second source/drain layer and the insulating layer; depositing indium oxide on an inner wall of the hole and a surface of the insulating layer to form an outer layer; depositing a channel material on the outer layer to form a channel layer, in which the channel layer further includes an inner layer made of indium oxide; and depositing a gate material on the inner layer to form a gate.

According to a third aspect of the present disclosure, there is provided a memory including a plurality of storage arrays which include the field effect transistor according to the first aspect.

According to a fourth aspect of the present disclosure, there is provided a display including a pixel circuit which includes the field effect transistor according to the first aspect.

According to the present disclosure, there is provided a field effect transistor, in which a gate of the transistor passes through a first source/drain layer and an insulating layer, and an annular channel surrounds the gate to form an architecture of Channel All Around (CAA), which is referred to as a transistor with CAA architecture. The transistor with CAA architecture according to the present disclosure has the following advantages compared to a transistor with FinFET architecture. Firstly, compared with a planar channel structure, a vertical channel structure reduces the horizontal area occupied by an electrode by stacking source/drain electrodes, which can significantly reduce the size of the transistor and facilitate reducing the device unit density. The channel length is determined by the thickness of the insulating layer, and the miniaturization of the channel length is not limited by the lithography process, which is conducive to achieve a smaller channel length, thereby increasing the channel width to length ratio, enabling greater device current and reducing power consumption. Secondly, the CAA architecture with the annular channel surrounding the gate can greatly increase the contact area between the gate and the channel layer, thereby significantly enhancing the control ability of the gate on the channel, and improving current conduction efficiency. Compared with the GAA (Gate All Around) architecture, the CAA architecture also has a larger contact area between the gate and channel. Thirdly, the outer layer of the channel layer in contact with the first source/drain layer and the second source/drain layer is made of indium oxide, which can improve the contact performance between the channel layer and the first source/drain layer and the second source/drain layer. The inner layer of the channel layer close to the gate is also made of indium oxide, which can improve the interface characteristics, thereby improving the sub-threshold characteristics and the operating current of the transistor.

The foregoing description is merely a summary of the technical solutions of the present disclosure. In order that the technical means of the present disclosure can be more clearly understood to be practiced in light of the description, and in order that the above and other objects, features and advantages of the present disclosure can be more clearly understood, the specific embodiments of the present disclosure are set forth as follows.

### BRIEF DESCRIPTION OF THE DRAWINGS

FIG. 1 is a structural schematic diagram of a field effect transistor according to an embodiment of the present disclosure;

FIG. 2 is an exploded schematic diagram of a layered structure of a channel layer according to an embodiment of the present disclosure;

FIG. 3 is a flow schematic diagram of a method for preparing a field effect transistor according to an embodiment of the present disclosure; and

FIG. 4 is a schematic diagram of a memory array according to an embodiment of the present disclosure.

Reference signs are denoted as follows:
1. first source/drain layer; 2. insulating layer; 3. second source/drain layer; 4. channel layer; 41. deposited sub-layer; 411. indium oxide layer; 412. gallium oxide layer; 413. zinc oxide layer; 42. inner layer; 5. gate; 6. gate dielectric layer; 71. first field effect transistor; 72. second field effect transistor.

### DETAILED DESCRIPTION OF THE INVENTION

In order that those skilled in the art to which the present disclosure belongs will more clearly understand the present disclosure, the following detailed description of the technical solutions of the present disclosure is set forth by way of specific embodiments in conjunction with the drawings. Throughout the specification, unless specifically stated otherwise, terms used herein shall be understood to have meanings as commonly used in the art. Accordingly, unless defined otherwise, all technical and scientific terms used herein have the same meaning as commonly understood by one of skill in the art to which the present disclosure belongs. In case of conflict, the specification takes precedence. Unless specifically stated otherwise, the various apparatuses and the like used in the present disclosure are commercially available or can be prepared by existing method.

In the description of the present disclosure, it should be noted that the terms “central”, “upper”, “lower”, “left”, “right”, “vertical”, “horizontal”, “inner”, “outer” and the like indicate an orientation or positional relationship based on that shown in the drawings, or the orientation or positional relationship in which the product of the invention is conventionally arranged in use is merely for ease of description of the present disclosure and simplification of the description, and is not intended to indicate or imply that the device or element referred to must have a particular orientation, be constructed and operate in a particular orientation, and therefore cannot be interpreted as limiting the present disclosure. Furthermore, the terms “first,” “second,” “third,” etc. are used merely for distinguishing descriptions and cannot be construed to indicate or imply relative importance.

Further, the terms “horizontal,” “vertical,” “hanging,” and the like do not imply a requirement that a component be absolutely horizontal or hanging, but may be slightly inclined. For example, “horizontal” merely means that its orientation is more horizontal than “vertical”, and does not mean that the structure must be completely horizontal, but may be slightly inclined.

In order to further reduce the size of a transistor and reduce power consumption, in a first aspect, according to the present disclosure, there is provided a field effect transistor (FET), whose structure is shown in FIG. 1, including:
a first source/drain layer 1, an insulating layer 2 and a second source/drain layer 3 stacked in sequence; and
a gate 5 and a channel layer 4 surrounding the gate 5, which are located in the second source/drain layer 3 and the insulating layer 2, in which the channel layer 4 is in contact with the first source/drain layer 1 and the second source/drain layer 3.

The FET provided in this embodiment has a vertical channel structure. For ease of understanding, the second source/drain layer 3 can be regarded as an upper source/drain of the FET, and the first source/drain layer 1 can be regarded as a lower source/drain of the FET. In actual use, the second source/drain layer 3 may be prepared as a source and the first source/drain layer 1 may be prepared as a drain, or the second source/drain layer 3 may be prepared as a drain and the first source/drain layer 1 may be prepared as a source, without any particular limitation. The optional material of the first source/drain layer 1 and the second source/drain layer 3 is at least one of titanium, titanium nitride, tungsten, molybdenum, gold, and silver.

The insulating layer 2 is located between the second source/drain layer 3 and the first source/drain layer 1, functioning as an insulating. The material of the insulating layer 2 may be SiO₂.

The gate 5 is of a vertical structure, and the bottom of the gate 5 at least penetrates the second source/drain layer 3 and enters the insulating layer 2. The bottom of the gate 5 may also penetrate the insulating layer 2 and enter the first source/drain layer 1. The shape of the gate 5 may be cylindrical, and its cross-sectional shape may be circular, elliptical or polygonal. The shape of the gate 5 can also be annular, and its cross-sectional shape can be a circular ring, an elliptical ring or a polygonal ring, which can be determined according to practical requirement. The optional materials for the gate 5 are Indium Tin Oxide (ITO), Indium Zinc Oxide (IZO) or Titanium Nitride (TiN).

The channel layer 4 is of a vertical channel structure, which is formed around the gate 5 within the second source/drain layer 3 and the insulating layer 2. Thus, the field effect transistor according to the present embodiment belongs to a Channel All Around (CAA) architecture in which an annular channel fully surrounds a gate. The cross-sectional shape of the channel layer 4 may be circular, elliptical, or polygonal, and the cross-sectional shape of the channel layer 4 may be the same as or different from the cross-sectional shape of the gate 5.

A preferred shape of the channel layer 4 is a shape with the largest cross-sectional perimeter selected under the premise that the cross-sectional area of the channel layer 4 remains unchanged, so that the channel width of the channel layer 4 can be increased, thereby further increasing the width-to-length ratio of the channel, which is beneficial to increase the saturation current of the field effect transistor.

In this embodiment, the optional material for the channel layer 4 is Indium Gallium Zinc Oxide (IGZO).

In some embodiments, as shown in FIG. 1, the field effect transistor further includes a gate dielectric layer 6 positioned between the gate 5 and the channel layer 4. Optional materials of the gate dielectric layer 6 include at least one of hafnium oxide, hafnium aluminum oxide, and aluminum oxide.

So far, a FET Transistor according to the present embodiment is provided, having a gate 5 passing through the first source/drain layer 1 and the insulating layer 2. An annular channel is disposed around the gate 5, thereby forming a Channel All Around in which a ring-shaped channel layer 4 is disposed around the gate 5, referred to as a transistor with CAA architecture. As compared to a transistor with FinFET architecture, the transistor with CAA architecture has the following characteristics.
1) Compared with a planar channel structure, a vertical channel structure reduces the horizontal area occupied by an electrode by stacking source/drain electrodes, which can significantly reduce the size of the transistor and facilitate reducing the device unit density. The channel length is determined by the thickness of the insulating layer 2, and the miniaturization of the channel length is not limited by the lithography process, which is conducive to achieve a smaller channel length, thereby increasing the channel width to length ratio, enabling greater device current and reducing power consumption.
2) The CAA architecture with the annular channel surrounding the gate can greatly increase the contact area between the gate 5 and the channel layer 4, thereby significantly enhancing the control ability of the gate 5 on the channel layer 4, and improving current conduction efficiency. Compared with the GAA (Gate All Around) architecture, the CAA architecture also has a larger contact area between the gate 5 and the channel layer 4.

In order to further improve the contact performance, the channel structure in the field effect transistor according to the present embodiment is adjusted as follows.

The channel layer 4 includes an outer layer and an inner layer. The inner layer is close to the gate 5, and the outer layer is in contact with the insulation layer 2, the first source/drain layer 1 and the second source/drain layer 3. Both the outer layer and the inner layer are made of indium oxide.

In particular, the channel layer 4 has a layered structure in which the inner layer is close to the gate 5, and the outer layer is in contact with the insulation layer 2 and the second source/drain layer 3. In addition, the materials of both the inner layer and the outer layer are indium oxide. This structural feature enables the FET provided in this embodiment to have the following advantages.
3) The material of the outer layer in the channel layer 4, which is in contact with the first source/drain layer 1 and the second source/drain layer 3, is indium oxide InOₓ, which can improve the contact performance between the channel layer 4, especially the IGZO channel layer 4, and the first source/drain layer 1 and the second source/drain layer 3. Further, the material of the region of the inner layer of the channel layer 4 closest to the gate 5 is also indium oxide, so that the interface characteristic can be improved and the sub-threshold characteristic and the operating current of the transistor can be improved.

The process of forming the layered channel may employ an atomic layer deposition method, and in particular, a plasma enhanced atomic layer deposition (PE-ALD) method.

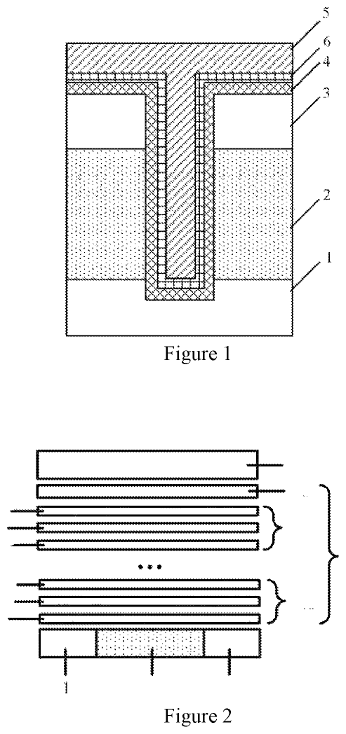

According to the present embodiment, IGZO channel is formed by depositing a sheet material by PE-ALD method, as shown in FIG. 2. The channel layer 4 further includes N deposited sub-layers 41, where N≥1 and is an integer. Each deposited sub-layer 41 includes an indium oxide layer 411, a gallium oxide layer 412, and a zinc oxide layer 413. The indium oxide layer 411 is close to the insulating layer 2, the zinc oxide layer 413 is close to the gate 5, and the gallium oxide layer 412 is between the zinc oxide layer 413 and the indium oxide layer 411.

In preparing the channel layer 4, a first source/drain layer 1, an insulating layer 2 and a second source/drain layer 3 are formed on a substrate, which are etched so as to form a hole. An indium oxide layer 411 in the first deposited sub-layer 41 is first deposited on the inner wall of the hole, and then a gallium oxide layer 412 and a zinc oxide layer 413 are deposited on the surface of the indium oxide layer 411 in the order, obtaining the first deposited sub-layer 41. The deposition process described above is repeated to deposit a plurality of deposited sub-layers 41. Thus, in the order of deposition, each deposited sub-layer 41 includes a three-sheet structure of InOₓ-GaOₓ-ZnOₓ from the outside to the inside, i.e. from the insulating layer 2 to the gate 5. At this time, the outer layer of the channel layer 4 is actually the InOₓ layer in the first deposited sub-layer 41 formed by deposition, and after the ZnOₓ deposition in the last deposited sub-layer 41 is completed, an additional InOₓ layer is deposited as the inner layer 42.

When it is deposited using the above deposition sequence, InOₓ and GaOₓ are adjacent, and there will be no situation where InOₓ is completely sandwiched by ZnOₓ, such as ZnOₓ-InOₓ-ZnOₓ. This is advantageous in suppressing the formation of oxygen vacancies and improving the controllability of the device. For the FET with CAA architecture according to the present embodiment, since the first source/drain layer 1 and the second source/drain layer 3 are deposited before the IGZO channel layer 4 is deposited, good contact characteristic and better interface characteristic can be obtained between the channel layer 4 and the source/drain, thereby further improving the sub-threshold characteristic and operating current of the device.

The total thickness of the IGZO channel layer 4 is about 3-5 nm in this embodiment. The thickness of each oxide layer deposited in cycled deposited sub-layers 41 is about several angstroms, and the thickness ratio of each layer is adjustable. In some embodiments, the thickness ratio of InOₓ: GaOₓ: ZnOₓ is 3:1: 1 to 6:1: 1.

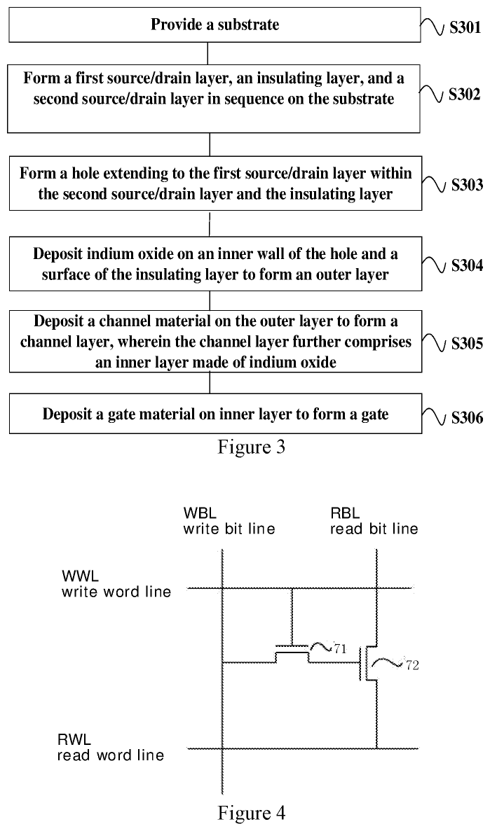

In a second aspect, according to the present disclosure, there is provided a method for preparing a field effect transistor, as shown in FIG. 3, including the steps S301 to S306 as follows.

S301: Provide a substrate, where a silicon substrate may be used.

S302: Form in sequence a first source/drain layer 1, an insulating layer 2, and a second source/drain layer 3 on the substrate.

In particular, a pre-oxidation layer may be deposited on the substrate with a thickness of 300-400 nm, followed by pre-cleaning, and then a metal material layer forming the first source/drain layer 1 may be deposited on the pre-oxidation layer as follows.

The pre-oxidation layer is pre-cleaned, and the source/drain metal material is deposited on the pre-cleaned pre-oxidation layer. A double protective layer is then deposited on the source/drain metal material layer, which may be a double layer protective layer formed of SiN and SiO, and the thickness of the double protective layer is about 200 nm. Next, the source/drain metal material layer is photolithographically processed. In particular, after the double protective layer is covered with the photoresist, exposure, development, and etching are performed in sequence to form a first source/drain layer 1.

Next, a fill oxide layer is deposited on the first source/drain layer 1, followed by chemical-mechanical polishing and cleaning, and after completion, an insulating layer material is deposited to form an insulating layer 2.

Next, the steps for the first source/drain layer 1 are repeated on the insulating layer 2 to deposit the source/drain metal material, and then deposition of a double protective layer, photoresist covering, exposure, development, etching, and cleaning are performed in sequence to form a second source/drain layer 3.

S303: Form a hole extending to the first source/drain layer 1 within the second source/drain layer 3 and the insulating layer 2, where the required hole can be formed by deep etching as follows.

A fill oxide deposition is performed again on the second source/drain layer 3, followed by chemical mechanical polishing and cleaning, with the polishing position resting on the fill oxide layer.

A through hole is formed as follows. A double protective layer (SiN+SiO) is deposited at the location where the through hole is to be formed, followed by covering of the photoresist, and then exposure, development, etching, cleaning and chemical mechanical polishing are performed, forming a through hole whose bottom reaches the first source/drain layer 1 and a through hole whose bottom reaches the second source/drain layer 3, respectively.

A channel hole is formed as follows. A double protective layer (SiN+SiO) is deposited at the location where the channel hole is to be formed, followed by covering of the photoresist. After aligning with the second source/drain layer 3, exposure, development, etching and cleaning are performed, forming a channel hole penetrating the second source/drain layer 3 and the insulating layer 2, whose bottom reaches the first source/drain layer 1.

S304: Deposit indium oxide on an inner wall of the hole and a surface of the insulating layer 2 to form an outer layer.

S305: Deposit a channel material on the outer layer to form the channel layer 4, in which the channel layer 4 further includes an inner layer 42 made of indium oxide. S306: Deposit a gate material on the inner layer 42 to form a gate 5.

In particular, the method for depositing a channel material and a gate material within a channel hole can be a plasma enhanced atomic layer deposition (PE-ALD) method.

In some embodiments, after deposition of the channel material, a gate dielectric material is deposited to form the gate dielectric layer 6, followed by deposition of a gate material on the surface of the gate dielectric layer 6. The method for depositing the gate dielectric material can also be atomic layer deposition.

In a third aspect, according to the present disclosure, there is provided a memory including a plurality of storage arrays which include the field effect transistor according to the first aspect.

FIG. 4 shows an alternative 2T0C memory array structure in which one storage array includes two field effect transistor according to the embodiment of the present disclosure, i.e., a first field effect transistor 71 and a second field effect transistor 72. Herein, the gate of the first field effect transistor 71 is electrically connected to a write word line (WWL), the source is electrically connected to a write bit line (WBL), and the drain is electrically connected to the gate of the second field effect transistor 72. The source of the second field effect transistor 72 is electrically connected to a read word line (RWL), and the drain is electrically connected to a read bit line (RBL).

By applying the field effect transistor according to the embodiment of the present disclosure to the memory circuit of 2T0C, the gate of one TFT transistor can be directly connected to the source/drain of another TFT transistor, without the need for external lead, and thus the volume of the entire memory can be greatly reduced to facilitate further miniaturization of the memory.

Furthermore, the field effect transistor according to the embodiment of the present disclosure can also be applied to memory arrays of 1T0C, 1TIC, and 2T1C, which are not particularly limited herein.

In a fourth aspect, according to the present disclosure, there is provided a display including a pixel circuit which includes the field effect transistor according to the first aspect.

Through one or more embodiments of the present disclosure, the present disclosure has the following benefits or advantages.

According to the present disclosure, there is provided a field effect transistor, in which a gate of the transistor passes through a first source/drain layer and an insulating layer, and an annular channel surrounds the gate to form an architecture of Channel All Around (CAA), which is referred to as a transistor with CAA architecture. The transistor with CAA architecture according to the present disclosure has the following advantages compared to a transistor with FinFET architecture. Firstly, compared with a planar channel structure, a vertical channel structure reduces the horizontal area occupied by an electrode by stacking source/drain electrodes, which can significantly reduce the size of the transistor and facilitate reducing the device unit density. The channel length is determined by the thickness of the insulating layer, and the miniaturization of the channel length is not limited by the lithography process, which is conducive to achieve a smaller channel length, thereby increasing the channel width to length ratio, enabling greater device current and reducing power consumption. Secondly, the CAA architecture with the annular channel surrounding the gate can greatly increase the contact area between the gate and the channel layer, thereby significantly enhancing the control ability of the gate on the channel, and improving current conduction efficiency. Compared with the GAA (Gate All Around) architecture, the CAA architecture also has a larger contact area between the gate and channel. Thirdly, the outer layer of the channel layer in contact with the first source/drain layer and the second source/drain layer is made of indium oxide, which can improve the contact performance between the channel layer and the first source/drain layer and the second source/drain layer. The inner layer of the channel layer close to the gate is also made of indium oxide, which can improve the interface characteristics, thereby improving the sub-threshold characteristics and the operating current of the transistor.

While preferred embodiments of the present disclosure have been described, further variations and modifications to these embodiments may be made by one of ordinary skill in the art, once the basic inventive concepts have come to mind. It is therefore intended that the appended claims be construed to include the preferred embodiments along with all changes and modifications that fall within the scope of the present disclosure.

It will be apparent to those skilled in the art that various modifications and variations can be made to the present disclosure without departing from the spirit and scope of the present disclosure. Thus, it is intended that the present disclosure includes such modifications and variations provided that they come within the scope of the present claims and their equivalents.

1. A field effect transistor comprising:
a first source/drain layer, an insulating layer and a second source/drain layer stacked in sequence; and
a gate and a channel layer surrounding the gate, which are located in the second source/drain layer and the insulating layer, wherein the channel layer is in contact with the first source/drain layer and the second source/drain layer,
wherein the channel layer comprises an outer layer and an inner layer, the inner layer is close to the gate, the outer layer is in contact with the insulating layer, the first source/drain layer and the second source/drain layer, and both the outer layer and the inner layer are made of indium oxide.

2. The field effect transistor according to claim 1, wherein the channel layer further comprises N deposited sub-layers, where N≥1 and is an integer,
each deposited sub-layer comprises an indium oxide layer, a gallium oxide layer, and a zinc oxide layer, wherein the indium oxide layer is close to the insulating layer, the zinc oxide layer is close to the gate, and the gallium oxide layer is between the zinc oxide layer and the indium oxide layer, and the outer layer is the indium oxide layer which is in contact with the gate.

3. The field effect transistor according to claim 1, wherein the thickness of the channel layer is 3 nm to 5 nm.

4. The field effect transistor according to claim 1, wherein the cross-sectional shape of the channel layer is one of circular, elliptical or polygonal.

5. The field effect transistor according to claim 1, further comprising a gate dielectric layer which is positioned between the gate and the channel layer.

6. The field effect transistor according to claim 1, wherein the material for the gate is one of Indium Tin Oxide, Indium Zinc Oxide or Titanium Nitride.

7. The field effect transistor according to claim 1, wherein the material for the first source/drain layer and the second source/drain layer is at least one of titanium, titanium nitride, tungsten, molybdenum, gold and silver.

8. A method for preparing a field effect transistor comprising:
providing a substrate;
forming a first source/drain layer, an insulating layer, and a second source/drain layer in sequence on the substrate;
forming a hole extending to the first source/drain layer within the second source/drain layer and the insulating layer;
depositing indium oxide on an inner wall of the hole and a surface of the insulating layer to form an outer layer;
depositing a channel material on the outer layer to form a channel layer, wherein the channel layer further comprises an inner layer made of indium oxide; and
depositing a gate material on inner layer to form a gate.

9. A memory comprising a plurality of storage arrays which comprise the field effect transistor according to claim 1.

10. A display comprising a pixel circuit which comprises the field effect transistor according to claim 1.
